(19) United States
(12) Patent Application Publication
(10) Pub. No.: US 2002/0014208 A1
(43) Pub. Date: Feb. 7, 2002

(54) Method of finish treating a steel blade for use in turbomachinery

(76) Inventors: Bruce Wynn Roberts, Rugby (GB); Kenneth Elwen Jones, Leicester (GB)

Correspondence Address: Kirschstein, Ottinger, Israel & Schiffmiller, P.C., 489 Fifth Avenue, New York, NY, 10017-6105, US

(21) Appl. No.: 09/886,945

(22) Filed: Jun. 21, 2001

(30) Foreign Application Priority Data
Jun. 21, 2000 (GB) 0015025.0

(51) Int. Cl. C23C 16/00

(52) U.S. Cl. 118/722

(57) ABSTRACT

A steel blade for turbomachinery, for example, a vane or blade of stainless steel for a steam turbine, has its working surface smoothed, for example, by tumble polishing, to a smoothness of about 0.25 microns Ra or less. Then the smoothed surface is subjected to plasma nitriding to harden the surface to a value of, for example, about 1000 on the Vickers hardness scale. The hardened nitrided layer in the steel can be 25 to 100 microns thick. The plasma nitriding process does not affect the smoothness of the area of surface being nitrided, and the resultant surface hardness preserves smoothness of the surface while the blade is in use.

### FIELD OF THE INVENTION

This invention relates to a method of finish treating the working surfaces of turbomachine blades made from steel. This invention also concerns steel blades treated by the method, which blades may be, for example, blades for axial flow steam turbines.

Where the word “blade” is used throughout this specification, it should be taken to embrace not only rotor and stator blades for turbomachinery, but also stator vanes, such as guide vanes located at the entry to a turbine. The words “turbomachinery” and “turbomachine” should be understood to embrace rotary bladed compressors as well as rotary bladed turbines. The “working surfaces” of a blade comprise its bucket or aerofoil convex (“suction”) and concave (“pressure”) surfaces aerofoil or other shapes of fluid-intercepting surfaces.

### BACKGROUND OF THE INVENTION

It has been found desirable to increase the aerodynamic efficiency of steam turbines by subjecting the working surfaces of the blades to final manufacturing processes, such as tumble polishing, which give extremely smooth surface finishes—so-called “super-finishes”—of better than 10 microinch Ra or 0.254 microns Ra (Ra is the roughness average which is the arithmetic average of substantially all roughness profile measurements). However, degradation of the working surfaces of steel blades, and hence turbine efficiency, can occur to varying degrees during steam turbine operation due to surface roughening caused by abrasion of the surfaces by solid particles passing through the turbine.

Solutions have been sought to prevent gross solid particle erosion (SPE), that is the massive removal of metal from a blade surface and which results in loss of turbine efficiency and power output. These solutions have generally involved the high velocity oxy-fuel (HVOF) application of hard coatings and have generally resulted in a lengthening of blade life. However, the as-deposited coatings are comparatively rough, typically 100 microinch Ra (2.54 microns Ra), and consequently are not useful for the proposed objective where the super-finish of less than 10 microinch Ra (0.254 microns Ra) is to be preserved.

The HVOF solution is unsatisfactory for two main reasons:(i)

The as-deposited surface finish is rough, and even expensive and time consuming finish polishing operations improve the finish to only about 60 microinch Ra (about 1.5 microns Ra).

(ii) A thick deposit (0.005 to 0.010 inches, say 127 to 254 microns) of the HVOF coating is usually required. Such a deposit significantly affects the form of the blade particularly at the thin trailing edge and thereby limits the blade efficiency. Also such deposits have a detrimental effect on the base material fatigue strength.

An alternative solution to avoiding gross SPE has been a so-called boronizing treatment. This comprises a high temperature diffusion of boron into the steel blade surface, resulting in a hard surface layer. This too has had limited success in service.

There are three main and significant disadvantages to the boronizing process:

(a) Following the process of diffusion, the component must be completely reheat treated to restore the base material properties. The consequences of such reheat treatment are the likely distortion of critically dimensioned components and a possible influence on the long term high temperature properties of the base material.

(b) Parts of the blade where the presence of such a coating is undesirable or not required, such as a blade root section, cannot be effectively masked from the effects of the diffusion treatment.

(c) The as-deposited coating is unavoidably craze cracked throughout the coating thickness. This can lead to both a loss of fatigue strength of the blade, and to a spalling of the coating, with consequent roughening, during service.

### SUMMARY OF THE INVENTION

An object of the invention is to provide a method of hardening super-finished working surfaces of steel turbomachine blades, particularly steam turbine blades, by which disadvantages associated with previous hardening methods may be avoided.

According to the present invention, a method of finish treating the working surface of a turbomachinery blade made of steel comprises the steps of applying a smoothing process to said surface to smooth said surface to a smoothness of about 0.25 microns Ra or less, and plasma nitriding the smoothed surface to harden said smoothed surface.

This method of treating a steel blade has the advantages that the aforesaid working surface can become hard (by reason of the nitriding) and thus resistant to surface roughening, while the finish or smoothness of the surface presented for plasma nitriding is retained. The method also has the further advantages that plasma nitriding is a diffusion process which provides more than just a mechanical bond in that nascent nitrogen hardens the surface of the steel by penetrating interstitially between the atoms forming the steel and also by combining with the iron in the steel to form iron nitride and, in the case of a stainless steel, by combining with the chromium in the steel to form chromium nitride. Also, the plasma nitriding process can readily and effectively be prevented, by masking, from affecting parts of the blade where hardening is not required, and the plasma nitriding process develops a compressive residual stress in the surface of the blade to thereby improve the fatigue strength of the blade.

The working surface may be hardened by plasma nitriding to at least about 750 on the Vickers hardness scale, and preferably to substantially 1000 on the Vickers hardness scale.

A nitrided layer of the steel at the working surface may have a thickness of at least about 25 microns. For example, the thickness of the nitrided layer may be in the range of approximately 25 microns to approximately 100 microns.

The steel is preferably a stainless steel, for example martensitic or austenitic stainless steel.

An example of the method of finish treating a steam turbine blade using smoothing and plasma nitriding processes is described below.

### DETAILED DESCRIPTION OF THE PREFERRED EMBODIMENT

A blade was made from martensitic stainless steel. An appropriate martensitic stainless steel comprises substantially 9% to substantially 13% chromium, but if desired an austenitic stainless steel comprising substantially 17% chromium may be used instead.

The blade was subject to a normal production process of forging (alternatively, casting) followed by machining where necessary. It was then tumble polished to produce a very smooth surface finish on the aerofoil section of the blade so that the blade had a super-finish of not substantially greater than 0.25 microns Ra and preferably less than 0.25 microns Ra. Prior to nitriding, the surface of each blade was thoroughly degreased. Then areas of the surface of the blade not requiring a hardened surface, such as the root region, were masked by a stop-off composition, known per se in the plasma nitriding art, which prevents hardening of the areas to which it is applied. A suitable stop-off composition comprises a copper-based paint, such as Condursal No. 9™.

To preserve the super-finish against roughening during the blade's service life and thus to maintain the efficiency of the turbine employing a set of such blades, the aerofoil section of the blade was subjected to plasma nitriding. This surface hardening by plasma nitriding does not, it is believed, alter the surface smoothness of the blade. The resulting surface hardness was substantially 1000 on the Vickers hardness scale but other values may be chosen.

For example the hardness may be lower than 1000 and may be as low as substantially 750 on the Vickers hardness scale. Preferably the nitrided layer in the steel has a thickness of at least about 25 microns, and may be in the range of approximately 25 microns to 100 microns.

The plasma nitriding was carried out in a metal vacuum vessel serving as a cathode connected to direct current (DC) supply connected to a workpiece forming an anode. High voltage electrical energy between the anode and cathode formed a plasma through which nitrogen ions were accelerated to strike the workpiece. This bombardment by ions heated the surface on which they impinged, and provided the monatomic nitrogen atoms or ions needed for nitriding the workpiece.

Important parameters of the nitriding process were as follows:

the nitriding atmosphere comprised of equal parts of nitrogen and hydrogen;

nitriding temperature was 450-550° C.;

workpiece heating and cooling rates were 50-100° C./hour, and

total nitriding cycle time was about 20 hours.

Further advantages, which are particularly applicable to the example given above, are that the plasma nitriding:

can be carried out at a temperature in the range of substantially 450° C. to 550° C. which is well below blade quality heat treatment temperatures normally used in standard processing of blade steels, and this will not degrade the long term mechanical properties of the blade steel;

can be carried out at a temperature which is above the maximum operating temperature to which the blade is subject in a steam turbine and thus significant changes in the surface hardness of the blade may be avoided over the time that the blade is in use, and

can be applied to a range of steels normally used for the manufacture of steam turbine blades.

The blades in the above example may be rotary or moving blades and fixed or stationary blades for steam turbines. In such a turbine, the moving blades are mounted in a rotor, and fixed blades may be mounted in an inner and outer ring to form a diaphragm in an impulse turbine or the fixed blades may be mounted directly into a casing or carrier in a reaction turbine. Together the moving and fixed blades form stages in the steam turbine, through which stages energy originally in the steam is transferred to the rotor. Hence maintaining the efficiency of the blades is of paramount importance.

It may be expected that super-finished surfaces of non-hardened blades in a steam turbine would roughen in use to a surface finish of about 1.6 microns Ra. Compared with plasma nitrided hardened steel blades as described with a roughness value of substantially 0.25 microns Ra, the loss of efficiency in a high pressure steam turbine due to roughening of non-hardened blades to 1.6 microns Ra may be up to 2% in the fixed blades and up to 0.6% in the moving blades. Thus smoothing the blades and plasma nitriding them according to the example is of definite benefit.

Whereas the above-described embodiments of the invention have been concerned with steam turbine blades, the method may also be applied to axial or radial flow compressor blades, e.g., for gas turbines.

We claim:

1. A method of finish treating a working surface of a turbomachinery blade made of steel, comprising the steps of: applying a smoothing process to the working surface to smooth the working surface to a smoothness of about 0.25 microns Ra or less, and plasma nitriding the smoothed surface to harden the smoothed surface.

2. The method as claimed in claim 1, in which the working surface is hardened by plasma nitriding to at least about 750 on the Vickers hardness scale.

3. The method as claimed in claim 2, in which the working surface is hardened by plasma nitriding to a hardness in the range of about 750 to about 1000 on the Vickers hardness scale.

4. The method as claimed in claim 1, in which a nitrided layer of the steel at the working surface has a thickness of at least about 25 microns.

5. The method as claimed in claim 4, in which the nitrided layer has a thickness in the range of about 25 microns to about 100 microns.

6. The method as claimed in claim 1, in which the steel is a stainless steel.

7. The method as claimed claim 1, in which the smoothing process comprises tumble polishing.

8. The method as claimed in claim 1, in which the turbomachinery blade comprises a blade or vane for a steam turbine.

9. A turbomachinery blade made of steel and having a working surface finish treated by applying a smoothing process to the working surface to smooth the working surface to a smoothness of about 0.25 microns Ra or less, and plasma nitriding the smoothed surface to harden the smoothed surface.

10. The turbomachinery blade as claimed in claim 9, comprising a steam turbine blade.

11. A steam turbine stage comprising a plurality of blades as claimed in claim 10.
